(19) United States
(12) Patent Application Publication
(10) Pub. No.: US 2010/0148769 A1
(43) Pub. Date: Jun. 17, 2010

(54) NON-CONTACT PLASMA-MONITORING APPARATUS AND METHOD AND PLASMA PROCESSING APPARATUS

(76) Inventors: SHIN-II CHOI, SEOUL (KR); HONG-KEE CHIN, SUWON-SI (KR); SANG-GAB KIM, SEOUL (KR); KI-YEUP LEE, SEOUL (KR); DONG-JU YANG, SEOUL (KR); YU-GWANG JEONG, YONGIN-SI (KR); SEUNG-HA CHOI, SIHEUNG-SI (KR); YUN-JONG YEO, SEOUL (KR); JI-YOUNG PARK, SUWON-SI (KR); HYUNG-JUN KIM, Daejeon (KR); SANG-SUN LEE, Daejeon (KR)

Correspondence Address: Innovation Counsel LLP, 21771 Stevens Creek Blvd, Ste. 200A, Cupertino, CA, 95014, US

(21) Appl. No.: 12/571,364

(22) Filed: Sep. 30, 2009

(30) Foreign Application Priority Data
Dec. 11, 2008 (KR) 10-2008-0125975

(51) Int. Cl. G01R 33/12

(52) U.S. Cl. 324/239

(57) ABSTRACT

A non-contact plasma-monitoring apparatus and a non-contact plasma-monitoring method are provided. The non-contact plasma-monitoring apparatus is installed in a plasma processing apparatus including a processing chamber and a power supply unit and measures at least one of an electric field and a magnetic field, which are created around power supply wiring connecting the process chamber to the power supply unit, without physically contacting the power supply wiring.

This application claims priority from Korean Patent Application No. 10-2008-0125975 filed on Dec. 11, 2008 in the Korean Intellectual Property Office, the disclosure of which is incorporated herein by reference in its entirety.

### BACKGROUND OF THE INVENTION

1. Field of the Invention

The present invention relates to a non-contact plasma-monitoring apparatus and method and a plasma processing apparatus, and more particularly, to a non-contact plasma-monitoring apparatus which can monitor the state of plasma without physically contacting a plasma processing apparatus, a non-contact plasma-monitoring method, and the plasma processing apparatus.

2. Description of the Related Art

A plasma processing apparatus includes a processing chamber, upper and lower electrodes which face each other within the processing chamber, and a power supply device which supplies power to the upper and lower electrodes to generate plasma. Generally, the plasma processing apparatus changes a reaction gas, which is supplied into a reaction chamber, into the plasma state by using power that is applied to the upper and lower electrodes from the power supply device.

In plasma processes using plasma, such as an etching process and a deposition process performed as part of the fabrication process of a liquid crystal display (LCD), the technology of monitoring the state of plasma is important to maintain the quality of the output of each plasma process. Therefore, research is being conducted on the technology of monitoring the state of plasma used in plasma processes.

### SUMMARY OF THE INVENTION

Aspects of the present invention provide a non-contact plasma-monitoring apparatus which can monitor the state of plasma in real time and be easily installed.

Aspects of the present invention also provide a plasma processing apparatus which can monitor the state of plasma in real time and in which a monitoring unit can be easily installed.

Aspects of the present invention also provide a non-contact plasma-monitoring method which can monitor the state of plasma in real time.

However, aspects of the present invention are not restricted to those set forth herein. The above and other aspects of the present invention will become more apparent to one of ordinary skill in the art to which the present invention pertains by referencing the detailed description of the present invention given below.

According to an aspect of the present invention, there is provided a non-contact plasma-monitoring apparatus which is installed in a plasma processing apparatus including a processing chamber and a power supply unit and which measures at least one of an electric field and a magnetic field, which are created around power supply wiring connecting the processing chamber to the power supply unit, without physically contacting the power supply wiring.

According to another aspect of the present invention, there is provided a plasma processing apparatus including: a processing chamber providing a reaction space; a power supply unit supplying power to the processing chamber; power supply wiring connecting the processing chamber to the power supply unit; and a non-contact plasma-monitoring unit measuring at least one of an electric field and a magnetic field, which are created around the power supply wiring, without physically contacting the power supply wiring.

According to another aspect of the present invention, there is provided a non-contact plasma-monitoring method including: providing a processing chamber having a reaction space in which a process using plasma is performed, a power supply unit which supplies power to the processing chamber, and power supply wiring which connects the processing chamber to the power supply unit; delivering power to the processing chamber via the power supply wiring; and measuring at least one of an electric field and a magnetic field, which are created around the power supply wiring, without physically contacting the power supply wiring.

### BRIEF DESCRIPTION OF THE DRAWINGS

The above and other aspects and features of the present invention will become more apparent by describing in detail embodiments thereof with reference to the attached drawings, in which:

FIG. 1 is a diagram showing a non-contact plasma-monitoring apparatus and method and a plasma processing apparatus according to an embodiment of the present invention;

FIG. 2 is a diagram showing the non-contact plasma-monitoring apparatus shown in FIG. 1;

FIG. 3 is a diagram showing a first sensor shown in FIG. 2;

FIG. 4 is a diagram showing a second sensor shown in FIG. 2;

FIG. 5 is a graph showing the effective values of an induced voltage and an induced current with respect to processing pressure;

FIG. 6 is a graph showing the effective values of the induced voltage and the induced current with respect to power;

FIG. 7A is a graph showing a waveform of the induced voltage according to processing pressure;

FIG. 7B is a graph showing a waveform of the induced current according to processing pressure; and

FIG. 8 is a diagram showing a non-contact plasma-monitoring apparatus and method and a plasma processing apparatus according to another embodiment of the present invention.

### DETAILED DESCRIPTION OF THE INVENTION

Advantages and features of the present invention and methods of accomplishing the same may be understood more readily by reference to the following detailed description of embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

It will be understood that when an element is referred to as being “connected to” or “coupled to” another element, it can be directly connected or coupled to the other element or intervening elements may be present. In contrast, when an element is referred to as being “directly connected to” or “directly coupled to” another element, there are no intervening elements present. Like numbers refer to like elements throughout. As used herein, the term “and/or” includes any and all combinations of one or more of the associated listed items.

It will be understood that, although the terms first, second, third, etc., may be used herein to describe various elements, components and/or sections, these elements, components and/or sections should not be limited by these terms. These terms are only used to distinguish one element, component or section from another element, component or section. Thus, a first element, component or section discussed below could be termed a second element, component or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated components, steps, operations, and/or elements, but do not preclude the presence or addition of one or more other components, steps, operations, elements, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

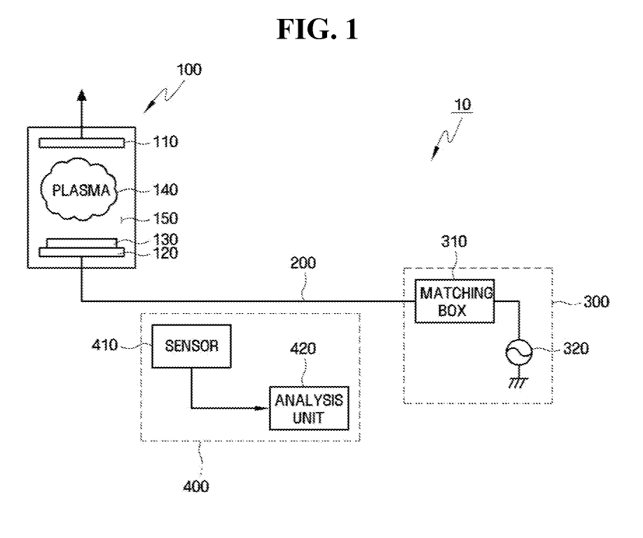

Hereinafter, a non-contact plasma-monitoring apparatus and method and a plasma processing apparatus according to an embodiment of the present invention will be described in detail with reference to FIGS. 1 through 7B.

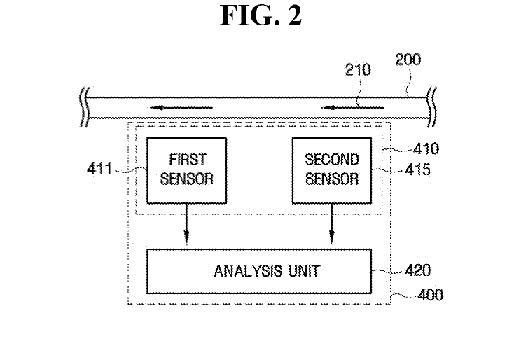

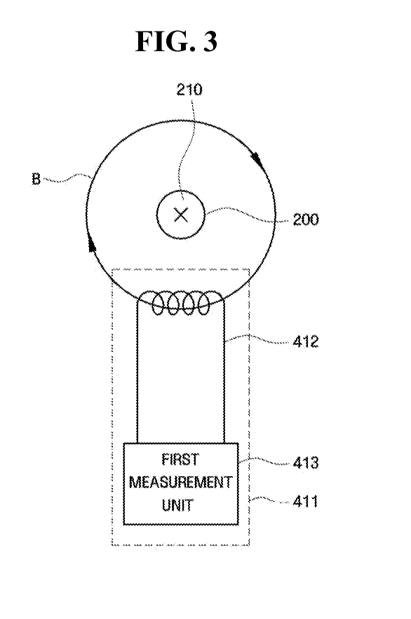

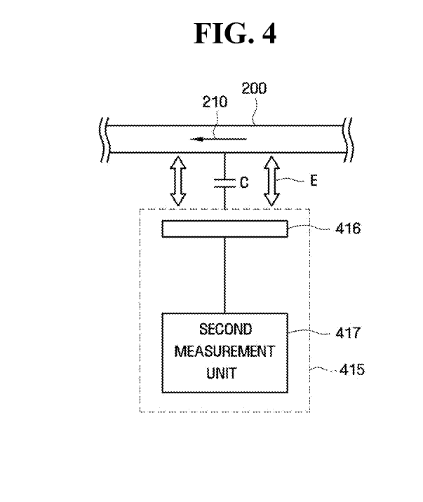

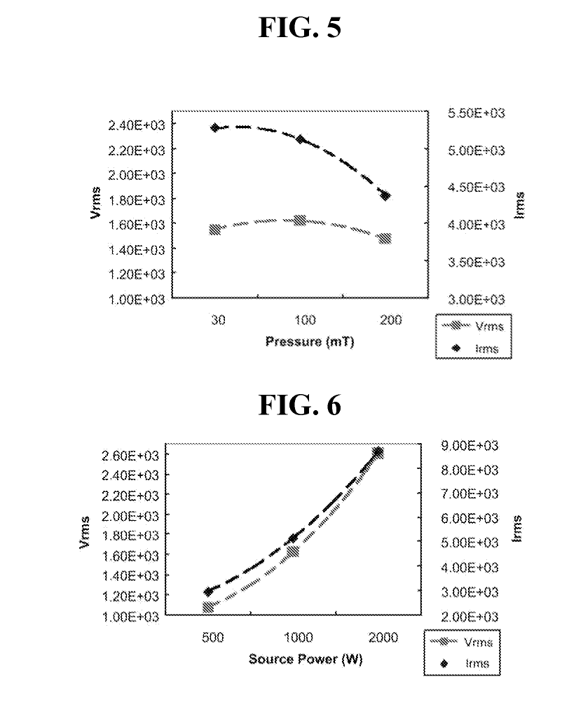

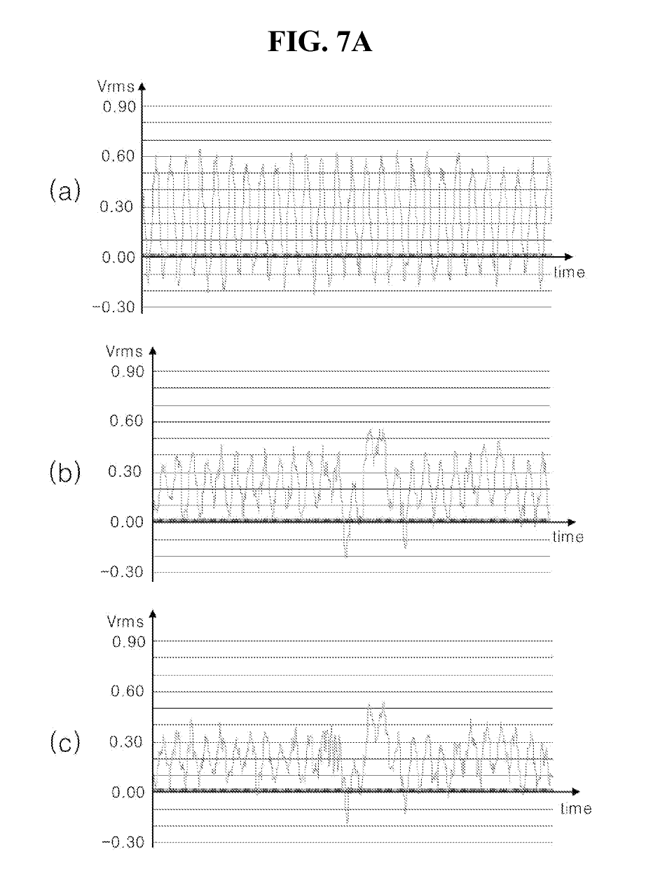

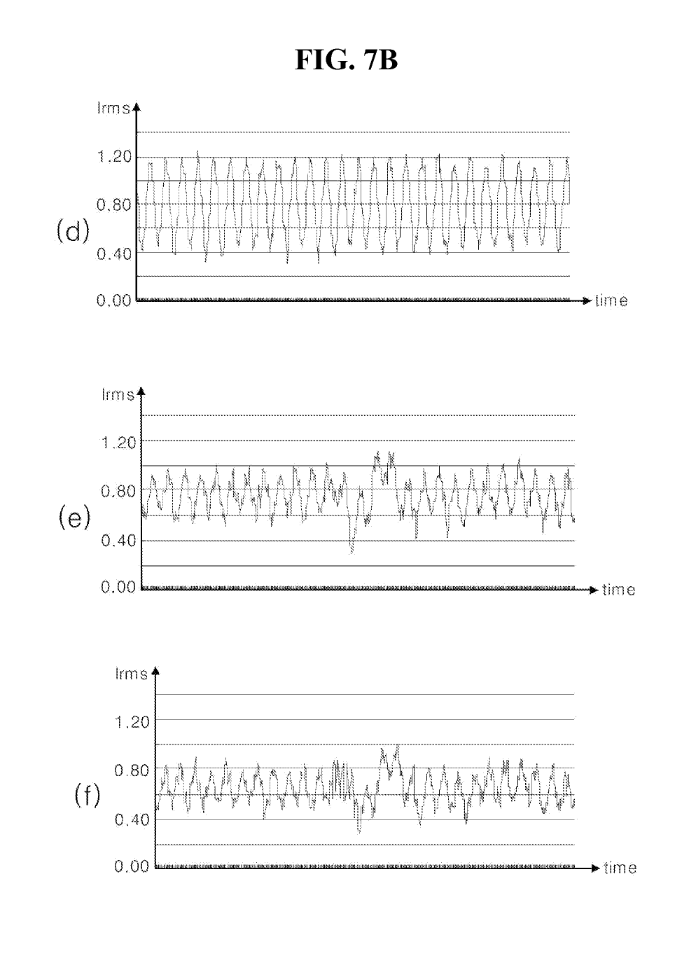

FIG. 1 is a diagram showing a non-contact plasma-monitoring apparatus and method and a plasma processing apparatus 10 according to an embodiment of the present invention. FIG. 2 is a diagram showing the non-contact plasma-monitoring apparatus shown in FIG. 1. FIG. 3 is a diagram showing a first sensor 411 shown in FIG. 2. FIG. 4 is a diagram showing a second sensor 415 shown in FIG. 2. FIG. 5 is a graph showing the effective values of an induced voltage and an induced current with respect to processing pressure. FIG. 6 is a graph showing the effective values of the induced voltage and the induced current with respect to power. FIG. 7A is a graph showing a waveform of the induced voltage according to processing pressure. FIG. 7B is a graph showing a waveform of the induced current according to processing pressure.

Referring to FIG. 1, the plasma processing apparatus 10 according to the present embodiment includes a processing chamber 100, a power supply unit 300, power supply wiring 200, and a non-contact plasma-monitoring unit 400.

The processing chamber 100 provides a reaction space 150 in which a process using plasma 140 is performed. Plasma may be a gas that is separated into electrons having negative charges and ions having positive charges at high temperatures. Specifically, plasma may be a gas that has a very high degree of charge separation and that is neutral since it contains equal numbers of negative and positive charges. A plasma processing apparatus according to embodiments of the present invention may be used in processes using plasma, such as an etching process and a deposition process. A protective film, such as alumina, may be coated on inner walls of the processing chamber 100. In addition, the processing chamber 100 may be grounded.

As shown in FIG. 1, the processing chamber 100 may include an upper electrode 110 and a lower electrode 120 which receive power from the power supply unit 300 and face each other. In addition, a substrate 130 may be disposed on, for example, the lower electrode 120. Although not shown in the drawing, an insulating plate may be disposed on an inner bottom surface of the processing chamber 100, and an electrode support may be disposed on the insulating plate. In addition, the lower electrode 120 may be disposed on the electrode support. A gas hole (not shown) may be formed in a lower surface of the upper electrode 110 such that gas can be supplied into the reaction space 150 inside the processing chamber 100 through the gas hole.

When power is applied to the upper and lower electrodes 110 and 120, electrons may be emitted from one of the upper and lower electrodes 110 and 120. If the energy of the emitted electrons is greater than the ionization energy of particles inside the processing chamber 100, the particles may be ionized by collision with electrons. As a result, the plasma 140 may be generated within the reaction space 150. While a process is being performed, the processing chamber 100 may be in a vacuum state. The above components of the processing chamber 100 are mere examples and may vary according to requirements of each process using the plasma 140.

The power supply unit 300 supplies power to the processing chamber 100. The power supply unit 300 may include a power generator 320 which generates power to be supplied to the processing chamber 100 and a matching box 310 which adjusts the level of the generated power and supplies the generated power with the adjusted level to the processing chamber 100. That is, when a plasma process begins, the power generator 320 may generate power, and a predetermined level of power may be supplied to the processing chamber 100 through the matching box 310.

The power generator 320 may supply, e.g., radio-frequency power. The power generator 320 may supply radio-frequency power having one frequency or different frequencies. When the power generator 320 supplies radio-frequency power having different frequencies to the processing chamber 100, a sensor unit 410 may measure the variation in electric current of the power supply wiring 200 for each frequency.

The matching box 310 may include a matching circuit which matches impedance on the side of the processing chamber 100 and impedance on the side of the power generator 320. Alternatively, the matching box 310 may control the impedance on the side of the power generator 320 by adjusting the level of power that is supplied to the processing chamber 100. The matching circuit or impedance control of the matching box 310 may be controlled by a control unit (not shown).

The power supply wiring 200 connects the processing chamber 100 to the power supply unit 300 and delivers power generated by the power supply unit 300 to the processing chamber 100.

The non-contact plasma-monitoring unit 400 measures at least one of an electric field and a magnetic field, which are created around the power supply wiring 200, without physically contacting the power supply wiring 200. The non-contact plasma-monitoring unit 400 may include the sensor unit 410 and an analysis unit 420. The sensor unit 410 senses the change in at least one of an electric field and a magnetic field which are created around the power supply wiring 200. The analysis unit 420 analyzes the change in the electric field and/or the magnetic field which is sensed by the sensor unit 410.

The fact that the non-contact plasma-monitoring unit 400 does not physically contact the power supply wiring 200 is meant to denote in one example that the non-contact plasma-monitoring unit 400 is not directly connected to electrical connection lines (e.g., electric wires) of the power supply wiring 200. That is, the power supply wiring 200 is not cut, and the non-contact plasma-monitoring unit 400 is not inserted between the cut portions of the power supply wiring 200 in order to directly and electrically connect the non-contact plasma-monitoring unit 400 to the power supply wiring 200.

The sensor unit 410 measures at least one of an electric field and a magnetic field, which are created around the power supply wiring 200, without physically contacting the power supply wiring 200. That is, the sensor unit 410 may be separated from the power supply wiring 200 by a distance range within which it can measure at least one of an electric field and a magnetic field created around the power supply wiring 200. The relationship between the sensor unit 410 and the power supply wiring 200 will be described in more detail later.

The analysis unit 420 may analyze the change in at least one of an electric field and a magnetic field which is sensed by the sensor unit 410. For example, the analysis unit 420 may receive an electrical signal, which reflects the change in at least one of an electric field and a magnetic field, from the sensor unit 410 and determine the state of the plasma 140 within the processing chamber 100 based on the received electrical signal. Here, the state of the plasma 140 may denote properties of the plasma 140, such as ion energy distribution.

Although not shown in the drawing, the analysis unit 420 may be connected to a display device (not shown) which displays the analysis result of the electrical signal which reflects the change in at least one of the electric field and the magnetic field. For example, a user may identify the state of the plasma 140 within the processing chamber 100 from the analysis result which is displayed on the display device.

Specifically, the analysis result displayed on the display device may be measurements of the changes in the electric field and/or the magnetic field created around the power supply wiring 200, where the electric field and/or the magnetic field are created by the change in electric current that flows through the power supply wiring 200. Here, the state (e.g., properties) of the plasma 140 within the processing chamber 100 changes according to the electric current that flows through the power supply wiring 200. Thus, the state of the plasma 140 within the processing chamber 100 can be identified or correlated based on the analysis result which is displayed on the display device.

The non-contact plasma-monitoring apparatus according to the present embodiment and the non-contact plasma-monitoring unit 400 shown in FIG. 1 will now be described in more detail with reference to FIG. 2.

The non-contact plasma-monitoring apparatus according to the present embodiment may correspond to the non-contact plasma-monitoring unit 400 of the plasma processing apparatus 10 in one embodiment. Therefore, both of them will be described together.

The non-contact plasma-monitoring apparatus (i.e., the non-contact plasma-monitoring unit 400 in FIG. 1) according to the present embodiment may include the sensor unit 410 and the analysis unit 420.

The sensor unit 410 may include a first sensor 411 which senses the change in a magnetic field created around the power supply wiring 200 and a second sensor 415 which senses the change in an electric field created around the power supply wiring 200. In FIG. 2, the sensor unit 410 includes both the first and second sensors 411 and 415. However, the sensor unit 410 may also include any one of the first and second sensors 411 and 415. Specifically, the sensor unit 410 may include only the first sensor 411 to sense the change in a magnetic field created around the power supply wiring 200 or include only the second sensor 415 to sense the change in an electric field created around the power supply wiring 200. Alternatively, the sensor unit 410 may include both the first and second sensors 411 and 415 to sense the changes in magnetic and electric fields created around the power supply wiring 200.

In FIG. 2, the non-contact plasma-monitoring apparatus includes one sensor unit 410. However, a plurality of sensor units, each including the first sensor 411 and/or the second sensor 415, may also be arranged in the non-contact plasma-monitoring apparatus. For example, two sensor units may be disposed at different locations around the power supply wiring 200, and the state of the plasma 140 within the processing chamber 100 may be monitored based on an electric field and/or a magnetic field measured by each sensor unit. For example, the average of an electric field and/or a magnetic field measured by the two sensor units may be used to monitor the state of the plasma 140.

The first and second sensors 411 and 415 may be disposed around the power supply wiring 200. The fact that the first and second sensors 411 and 415 are disposed around the power supply wiring 200 may denote that they are disposed adjacent to the power supply wiring 200 without physically contacting the power supply wiring 200. Specifically, each of the first and second sensors 411 and 415 may be separated from the power supply wiring 200 by a distance at which it can measure a magnetic field or an electric field created around the power supply wiring 200. That is, the first sensor 411 may be separated from the power supply wiring 200 by a distance at which it can sense the change in a magnetic field created around the power supply wiring 200, and the second sensor 415 may be separated from the power supply wiring 200 by a distance at which it can sense the change in an electric field created around the power supply wiring 200. Therefore, the distance between the power supply wiring 200 and the first sensor 411 may be different from the distance between the power supply wiring 200 and the second sensor 415.

As shown in FIG. 2, current 210, which corresponds to power supplied by the power supply unit 300 (see FIG. 1), may flow through the power supply wiring 200. As the current 210 flowing through the power supply wiring 200 varies, an electric field and a magnetic field may be generated around the power supply wiring 200, and the first and second sensors 411 and 415 may sense the magnetic field and the electric field, respectively. Then, the magnetic and electric fields sensed by the first and second sensors 411 and 415, respectively, may be transmitted to the analysis unit 420. Thus, the state of the plasma 140 (see FIG. 1) within the processing chamber 100 (see FIG. 1) can be monitored based on the sensed magnetic and/or electric fields.

Each of the first and second sensors 411 and 415 can measure an electric field or a magnetic field, which is created around the power supply wiring 200, in real time. Accordingly, the state of the plasma 140 within the processing chamber 100 can be monitored in real time by using the first and second sensors 411 and 415. Previously, outputs of a plasma process were monitored after the completion of the plasma process. However, it is now possible to monitor the plasma process, instead of its outputs, in real time during the actual plasma process. When the plasma process itself is monitored, processing efficiency can be significantly increased as compared to when the outputs of the plasma process are monitored.

As described above, the power generator 320 (see FIG. 1) may supply radio-frequency power having two or more different frequencies. In this case, the analysis unit 420 may receive an induced current and an induced voltage sensed by the first and second sensors 411 and 415, respectively, and obtain the change in the current 210 of the power supply wiring 200 for each frequency by using a mathematical analysis method, for example, the Fourier transform.

Referring to FIG. 3, the first sensor 411 may include a pickup coil 412 which is disposed adjacent to the power supply wiring 200 and a first measurement unit 413 which measures electric current flowing through the pickup coil 412.

Around the power supply wiring 200, a magnetic field B is created by the current 210 that flows through the power supply wiring 200. The change in the current 210 of the power supply wiring 200 may create the magnetic field B, and the change in the magnetic field B over time may generate an induced electromotive force. Accordingly, an induced current may be generated in the pickup coil 412 which is disposed adjacent to the power supply wiring 200. That is, the change in a magnetic field, which is created around the power supply wiring 200 by the change in the current 210 of the power supply wiring 200, may cause an induced current to flow through the pickup coil 412. Here, the pickup coil 412 may be a conducting wire in one example.

The fact that the pickup coil 412 is “disposed adjacent” to the power supply wiring 200 may denote that it is separated from the power supply wiring 200 by a distance range within which it can substantially measure a magnetic field created around the power supply wiring 200. Specifically, when power is supplied to the processing chamber 100, a magnetic field is generated mainly around the power supply wiring 200. Thus, as the distance from the power supply wiring 200 increases, the intensity of the magnetic field may gradually be reduced. For this reason, the pickup coil 412 may be separated from the power supply wiring 200 by a distance range within which it can sense an induced current by a magnetic field that is created around the power supply wiring 200.

For example, as shown in FIG. 3, the current 210 may flow in a direction from the front to the rear of the drawing, that is, the current 210 may pass through a plane, which contains the drawing, in a direction perpendicular to the plane. When the current 210 flows in the above direction, the magnetic field B may be created around the power supply wiring 200 in a clockwise direction. In this case, the pickup coil 412 disposed within the magnetic field B may detect an induced current by the change in the magnetic field B. In addition, the first measurement unit 413 may be connected to the pickup coil 412 and thus measure the induced current that flows through the pickup coil 412. The first measurement unit 413 may include, for example, a galvanometer.

The first sensor 411 may sense an induced current by the change in the magnetic field B. The induced current may be generated in the pickup coil 412 by electromagnetic induction, and the first measurement unit 413 may measure the induced current that flows through the pickup coil 412. The measured induced current may be transmitted to the analysis unit 420 (see FIG. 1).

Referring to FIG. 4, the second sensor 415 may include a detection electrode 416 which is disposed adjacent to the power supply wiring 200 and a second measurement unit 417 which measures a voltage applied to the detection electrode 416. The second sensor 415 is different from the first sensor 411 in that it senses an induced voltage by the change in an electric field E. However, the second sensor 415 is conceptually similar to the first sensor 411 in that it is affected by the change in the current 210 flowing through the power supply wiring 200.

Around the power supply wiring 200, the electric field E is created by the current 210 that flows through the power supply wiring 200. The change in the current 210 of the power supply wiring 200 may create the electric field E, and the change in the electric field E over time may generate a displacement current. Accordingly, an induced voltage may be generated in the detection electrode 416 which is disposed adjacent to the power supply wiring 200. That is, the change in an electric field, which is created around the power supply wiring 200 by the change in the current 210 of the power supply wiring 200, may cause an induced voltage to be applied to the detection electrode 416.

Like the pickup coil 412 described above, the fact that the detection electrode 416 is “disposed adjacent” to the power supply wiring 200 may denote that it is separated from the power supply wiring 200 by a distance range within which it can substantially measure an electric field created around the power supply wiring 200. Specifically, when power is supplied to the processing chamber 100, an electric field is generated mainly around the power supply wiring 200. Thus, as the distance from the power supply wiring 200 increases, the intensity of the electric field may gradually be reduced. For this reason, the detection electrode 416 may be separated from the power supply wiring 200 by a distance range within which it can sense an induced voltage by an electric field that is created around the power supply wiring 200.

For example, as shown in FIG. 4, when the current 210 flows from right to left, the electric field E may be created around the power supply wiring 200. In this case, an electrostatic capacitor C may be formed between the detection electrode 416, which is disposed within the electric field E, and the power supply wiring 200. Based on the electrostatic capacitor C, the detection electrode 416 may detect an induced voltage by the change in the electric field E. In addition, the second measurement unit 417 may be connected to the detection electrode 416 and thus measure an induced voltage that flows through the detection electrode 416. The second measurement unit 417 may include, for example, a voltmeter.

The second sensor 415 may sense an induced voltage by the change in the electric field E. Specifically, the detection electrode 416 may sense an induced voltage, and the second measurement unit 417 may measure an induced voltage that is applied to the detection electrode 416. The measured induced voltage may be transmitted to the analysis unit 420 (see FIG. 1).

The analysis unit 420 will now be described in more detail with reference to FIGS. 5 through 7B.

The analysis unit 420 (see FIG. 2) may define an induced current and an induced voltage, which correspond to power required to perform a plasma process normally, as a unique current and a unique voltage, respectively. As shown in the graphs of FIGS. 5 through 7B, an induced current and an induced voltage for each processing condition may be used as the unique current and the unique voltage, respectively.

Specifically, the analysis unit 420 may compare an effective value of an induced current sensed by the first sensor 411 according to the current 210 of the power supply wiring 200 with that of the unique current and compare an effective value of an induced voltage sensed by the second sensor 415 according to the current 210 of the power supply wiring 200 with that of the unique voltage.

For example, the graph of FIG. 5 shows effective values of an induced current and an induced voltage at processing pressures of 30 mT, 100 mT, and 200 mT for a power of 1000 W, an O₂ flow rate of 400 sccm, and a processing time of 60 sec. As shown in the graph, the effective values of the induced current and the induced voltage change insignificantly with respect to processing pressure. However, it can be understood from the graph that the effective values of the induced current and the induced voltage are reduced as the processing pressure increases. Here, since the effective value of the induced current changes more significantly than that of the induced voltage with respect to pressure, the induced current changes may be more useful data for monitoring the state of plasma.

The graph of FIG. 6 shows effective values of an induced current and an induced voltage at powers of 500 W, 1000 W, and 2000 W for a processing pressure of 100 mT, an O₂ flow rate of 400 sccm, and a processing time of 60 sec. It can be understood from the graph that both the induced current and the induced voltage are increased as power increases. Since the effective values of the induced current and the induced voltage have unique values for each processing condition, they can be used as data for monitoring the state of plasma, that is, used as the effective values of the unique current and the unique voltage, respectively.

For example, the analysis unit 420 may define effective values of an induced current and an induced voltage for a processing condition, which corresponds to power required to perform a plasma process normally, as those of the unique current and the unique voltage, respectively. Then, the analysis unit 420 may compare effective values of an induced current and an induced voltage received from the sensor unit 410 (see FIG. 2) during the plasma process with the effective values of the unique current and the unique voltage, respectively. Based on the comparison result, the state of the plasma 140 within the processing chamber 100 can be determined Here, since the sensor unit 410 can sense the induced current and the induced voltage of the power supply wiring 200 in real time, the analysis unit 420 can monitor the state of the plasma 140 in real time.

In another example, the analysis unit 420 may compare a waveform of an induced current sensed by the first sensor 411 (see FIG. 3) according to the current 210 of the power supply wiring 200 with that of the unique current and compare a waveform of an induced voltage sensed by the second sensor 415 (see FIG. 4) according to the current 210 of the power supply wiring 200 with that of the unique voltage.

The graphs of FIG. 7A show waveforms of an induced current and an induced voltage at different processing pressures for a power of 1000 W, an O₂ flow rate of 400 sccm, and a processing time of 60 sec. The horizontal axis of each graph represents time (in microseconds), and the vertical axis represents the size of an induced voltage or an induced current.

Specifically, graphs (a) through (c) of FIG. 7A show waveforms of an induced voltage for processing pressures of 30 mT, 100 mT, and 200 mT, respectively. Graphs (d) through (f) of FIG. 7B show waveforms of an induced current for processing pressures of 30 mT, 100 mT, and 200 mT, respectively. The waveforms of the induced current and the induced voltage may be measured by using, for example, an oscilloscope. Since the induced current and the induced voltage have unique waveforms for each processing condition, they can be used as data for monitoring the state of plasma, that is, used as waveforms of the unique current and the unique voltage, respectively.

For example, the state (such as ion energy distribution) of plasma within a processing chamber can be estimated based on the degree to which the phase of a waveform of an induced current is shifted from the phase of a waveform of the unique current. Likewise, the state of the plasma within the processing chamber can be estimated based on the degree to which the phase of a waveform of an induced voltage is shifted from the phase of a waveform of the unique voltage. As described above, the waveform of the induced current or voltage may be compared with that of the unique current or voltage in order to estimate the state of plasma. Alternatively, both the waveform of the induced current and the waveform of the induced voltage may be compared with those of the unique current and the unique voltage, respectively. The same applies when the state of the plasma is estimated by using effective values.

In conclusion, the analysis unit 420 can monitor the state of the plasma 140 within the processing chamber 100 by analyzing an induced current and an induced voltage, which are sensed by the changes in a magnetic field and an electric field created around the power supply wiring 200, based on unique effective values or waveforms of an induced current and an induced voltage for each processing condition. Furthermore, the analysis unit 420 can measure the state of the plasma 140 in real time.

The non-contact plasma-monitoring apparatus and method and the plasma processing apparatus 10 according to the embodiments of the present invention can measure at least one of an electric field and a magnetic field created around the power supply wiring 200 without physically contacting the power supply wiring 200. Thus, the non-contact plasma-monitoring unit 400 can be installed outside the power supply wiring 200. That is, the non-contact plasma-monitoring unit 400 can be installed easily. In addition, since an electric field and a magnetic field corresponding to the current 210 that flows through the power supply wiring 200 are measured, a plasma process itself can be monitored in real time while it is being performed.

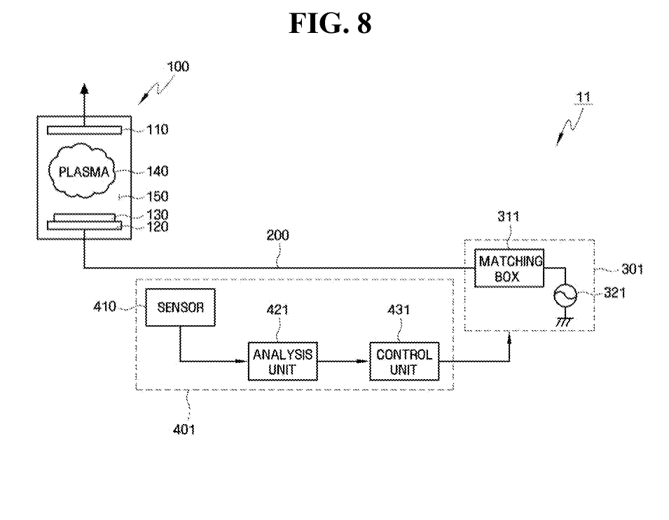

Hereinafter, a non-contact plasma-monitoring apparatus and method and a plasma processing apparatus according to another embodiment of the present invention will be described in detail. FIG. 8 is a diagram showing a non-contact plasma-monitoring apparatus and method and a plasma processing apparatus 11 according to another embodiment of the present invention.

The non-contact plasma-monitoring apparatus and method and the plasma processing apparatus 11 according to the present embodiment further use a control unit 431 which receives analysis data of an induced current and an induced voltage from an analysis unit 421 and controls a power supply unit 301 based on the received analysis data. For simplicity, a description of elements substantially identical to those of the previous embodiment will be omitted or simplified.

Referring to FIG. 8, the plasma processing apparatus 11 according to the present embodiment includes a processing chamber 100, the power supply unit 301, power supply wiring 200, and a non-contact plasma-monitoring unit 401.

The non-contact plasma-monitoring unit 401 measures at least one of an electric field and a magnetic field created around the power supply wiring 200 without physically contacting the power supply wiring 200. The non-contact plasma-monitoring unit 401 includes a sensor unit 410, the analysis unit 421, and the control unit 431.

The control unit 431 may receive data on an analysis of the change in at least one of an electric field and a magnetic field created around the power supply wiring 200 and, when a plasma process is being performed abnormally, generate a control signal for controlling power supplied by the power supply unit 301. In response to the control signal of the control unit 431, the power supply unit 301 may control at least one of a matching box 311 and a power generator 321 so that the plasma process can be performed normally. That is, the control unit 431 may adjust the level of power to be supplied to the processing chamber 100 so that the state of plasma 140 can become suitable for the plasma process.

For example, the sensor unit 410 of the non-contact plasma-monitoring unit 401 may sense an induced current and/or an induced voltage by the change in at least one of an electric field and a magnetic field which are created around the power supply wiring 200. Then, the analysis unit 421 may make a comparative analysis of the sensed induced current and/or the sensed induced voltage and a unique current and/or a unique voltage. Based on data of the comparative analysis, the control unit 431 may transmit a control signal to the power supply unit 301 in order to control the power supply unit 301 to supply power sufficient to make the state of the plasma 140 within the processing chamber 100 become suitable for the plasma process.

As mentioned above in the previous embodiment, the non-contact plasma-monitoring unit 401 of the plasma processing apparatus 11 according to the present embodiment may be substantially identical to the non-contact plasma-monitoring apparatus according to the present embodiment. Thus, a description of the non-contact plasma-monitoring apparatus according to the present embodiment will be omitted.

In the non-contact plasma-monitoring apparatus and method and the plasma processing apparatus 11 according to the present embodiment, the non-contact plasma-monitoring unit 401 can be installed easily, and a plasma process itself can be monitored in real time. In addition, a voltage supplied to the processing chamber 100 can be controlled in real time to keep the state of the plasma 140 within the processing chamber 100 suitable for a plasma process.

While the present invention has been particularly shown and described with reference to embodiments thereof, it will be understood by those of ordinary skill in the art that various changes in form and detail may be made therein without departing from the spirit and scope of the present invention as defined by the following claims. The embodiments should be considered in a descriptive sense only and not for purposes of limitation.

What is claimed is:

1. A non-contact plasma-monitoring apparatus which is installed in a plasma processing apparatus comprising a processing chamber and a power supply unit and which measures at least one of an electric field and a magnetic field, which are created around power supply wiring connecting the process chamber to the power supply unit , without physically contacting the power supply wiring.

2. The apparatus of claim 1, wherein the state of plasma within the processing chamber is monitored based on at least one of the measured electric field and the measured magnetic field.

3. The apparatus of claim 1, wherein at least one of the electric field and the magnetic field is measured in real time.

4. The apparatus of claim 1, comprising a first sensor which senses a change in the magnetic field created around the power supply wiring.

5. The apparatus of claim 4, comprising a second sensor which senses a change in the electric field created around the power supply wiring.

6. The apparatus of claim 5, wherein the first sensor comprises a pickup coil which is disposed adjacent to the power supply wiring and a first measurement unit which measures current flowing through the pickup coil, and the second sensor comprises a detection electrode which is disposed adjacent to the power supply wiring and a second measurement unit which measures a voltage applied to the detection electrode.

7. The apparatus of claim 5, wherein the first sensor senses an induced current by the change in the magnetic field, the second sensor senses an induced voltage by the change in the electric field, and the induced current and the induced voltage, which correspond to the power required to perform the process normally, are defined as a unique current and a unique voltage, respectively.

8. The apparatus of claim 7, further comprising an analysis unit which analyzes the induced current and the induced voltage, wherein the analysis unit monitors the state of the plasma in real time by comparing an effective value of an induced current, which is received from the first sensor during a plasma process, with an effective value of the unique current and comparing an effective value of an induced voltage, which is received from the second sensor during the plasma process, with an effective value of the unique voltage.

9. The apparatus of claim 7, further comprising an analysis unit which analyzes the induced current and the induced voltage, wherein the analysis unit monitors the state of the plasma in real time by comparing a waveform of an induced current, which is received from the first sensor during a plasma process, with a waveform of the unique current and comparing a waveform of an induced voltage, which is received from the second sensor during the plasma process, with a waveform of the unique voltage.

10. The apparatus of claim 1, comprising a second sensor which senses the change in the electric field created around the power supply wiring and comprises a detection electrode which is disposed adjacent to the power supply wiring and a second measurement unit which measures a voltage applied to the detection electrode.

11. The apparatus of claim 1, wherein the power supply unit supplies radio-frequency power.

12. The apparatus of claim 11, wherein, when the radio-frequency power has two or more different frequencies, a change in current flowing through the power supply wiring is measured for each of the frequencies of the radio-frequency power by using a Fourier transform.

13. A plasma processing apparatus comprising:
a processing chamber providing a reaction space;
a power supply unit supplying power to the processing chamber;
power supply wiring connecting the processing chamber to the power supply unit; and
a non-contact plasma-monitoring unit measuring at least one of an electric field and a magnetic field, which are created around the power supply wiring, without physically contacting the power supply wiring.

14. The apparatus of claim 13, wherein the non-contact plasma-monitoring unit comprises:
a first sensor sensing a change in the magnetic field created around the power supply wiring and comprising a pickup coil which is disposed adjacent to the power supply wiring and a first measurement unit which measures current flowing through the pickup coil; and
a second sensor sensing a change in the electric field created around the power supply wiring and comprising a detection electrode which is disposed adjacent to the power supply wiring and a second measurement unit which measures a voltage applied to the detection electrode.

15. A non-contact plasma-monitoring method comprising:
providing a processing chamber having a reaction space in which a process using plasma is performed, a power supply unit which supplies power to the processing chamber, and power supply wiring which connects the processing chamber to the power supply unit;
delivering power to the processing chamber via the power supply wiring; and
measuring at least one of an electric field and a magnetic field, which are created around the power supply wiring, without physically contacting the power supply wiring.

16. The method of claim 15, further comprising monitoring the state of plasma within the processing chamber based on at least one of the measured electric field and the measured magnetic field.

17. The method of claim 15, wherein the measuring of the at least one of the electric field and the magnetic field created around the power supply wiring comprises measuring at least one of the electric field and the magnetic field in real time.

18. The method of claim 15, wherein the measuring of the at least one of the electric field and the magnetic field created around the power supply wiring comprises at least one of sensing a change in the magnetic field created around the power supply wiring and sensing a change in the electric field created around the power supply wiring, wherein the sensing of the change in the magnetic field comprises measuring an induced current that flows through a pickup coil disposed adjacent to the power supply wiring, and the sensing of the change in the electric field comprises measuring an induced voltage that is applied to a detection electrode disposed adjacent to the power supply wiring.

19. The method of claim 15, wherein the measuring of the at least one of the electric field and the magnetic field created around the power supply wiring comprises supplying radio-frequency power by using the power supply unit and, when the radio-frequency power has two or more different frequencies, measuring a change in current which flows through the power supply wiring for each of the frequencies of the radio-frequency power by using a Fourier transform.
